(19) United States
(12) Patent Application Publication
(10) Pub. No.: US 2026/0101605 A1
(43) Pub. Date: Apr. 9, 2026

(54) METHOD AND DEVICE FOR FABRICATING PHOTODETECTOR

(71) Applicants: Secretary, Ministry of Electronics and Information Technology, Govt. of India, New Delhi (IN); The Director General, Centre for Materials for Electronics Technology (C-MET), Pune (IN)

(72) Inventors: Seema Ansari, Thrissur (IN); Muralidharan Malamal Neelanchery, Thrissur (IN); Thomas Daniel, Thrissur (IN); Partha Kumbhakar, Thrissur (IN)

(21) Appl. No.: 18/909,806

(22) Filed: Oct. 8, 2024

(30) Foreign Application Priority Data
Oct. 9, 2023 (IN) 202311067662

(51) Int. Cl. H01L 31/18; H01L 31/032; H01L 31/108

(52) U.S. Cl. CPC H10F 71/00; H10F 30/2275; H10F 77/12

(57) ABSTRACT

Embodiments of present disclosure relates to a method and a device for fabricating photodetector. The device is configured to receive a substrate of a predefined dimension based on user requirement for fabricating the photodetector. The device is configured to develop a first electrode and a second electrode on the substrate. The device is configured to generate a predefined range of micrometer gap between the first electrode and the second electrode. The device is configured to cast the predefined range of micrometer gap using a light-sensitive metal-oxide material. Thus, the present disclosure is able to generate a photodetector at low-cost and reduced fabrication time.

### CROSS REFERENCE TO RELATED APPLICATIONS

This application claims priority to Indian Patent Application number 202311067662, filed Oct. 9, 2023, the entire contents of which are incorporated herein by reference.

### TECHNICAL FIELD

The present subject matter is related in general to photodetectors, but not exclusively, the present subject matter relates to a method and a device for fabricating photodetectors.

### BACKGROUND

Metal-semiconductor-metal (MSM) photodetector planar structure allows for easy integration of metal and semiconductors and can be fabricated on a variety of substrates. However, the fabrication of optoelectronic-based microdevices requires a complex miniature pattern. Microfabrication is a technique that is widely used in production/generation of miniature patterns in a variety of industries. However, the technique demands sophisticated equipment that is expensive and state-of-the-art in terms of deposition, patterning, and etching. As a result, these traditional/conventional methods are both time and resource intensive.

Further, printed electronics is an alternative fabrication method that uses organic and inorganic semiconducting materials. However, printing of inorganic materials for electronic applications is not widely used. The use of inorganic materials has better performance and more stable characteristics with high intrinsic mobility than organic semiconductors.

Currently, the most widely used printing technologies are inkjet, roll-to-roll printing gravure and screen printing. Inkjet printing is a type of computer printing that recreates a digital image by propelling droplets of ink onto paper and plastic substrates. Further, inkjet printers are presently being used to create electronic devices by printing oxide semiconductors. Although this technology is popular due to its simplicity, it lacks high precision and fine resolution. Roll-to-roll printing technologies work well for high volume production but require molds, masks, and engravings. Further, though screen printing requires fewer resources, separate stencils, masks/meshes, and squeegees are required for different designs and patterns.

At present, for the fabrication of electronic components printed electronics have recently gained popularity as an alternative to photolithography-based microelectronic fabrication technology. The electronic components may include, but are not limited to, a resistor, a diode, a capacitor, an inductor, an organic and inorganic field-effect transistor. The technology is beneficial for rapid prototyping and cost-effective production. However, inorganic materials, such as Argentum (Ag) nanoparticles, are typically deposited using traditional electronic manufacturing techniques, which necessitate costly equipment and lengthy fabrication processes.

Further currently, optical detection is achieved using zinc oxide (ZnO), titanium dioxide (TiO₂), tin oxide (SnO₂), tungsten oxide (WO₃), and vanadium pentoxide (V₂O₅). The optical absorptions, however, are limited to a particular wavelength. Thus, there is a need for fabricating broad band photodetectors at low cost and reduced fabrication time.

The information disclosed in this background of the disclosure section is only for enhancement of understanding of the general background of the invention and should not be taken as an acknowledgement or any form of suggestion that this information forms the prior art already known to a person skilled in the art.

### SUMMARY

In an embodiment, the present disclosure relates to a method for fabricating a photodetector. The method comprises receiving a substrate for fabricating the photodetector, wherein the substrate is of a predefined dimension based on user requirement. The method comprises developing a first electrode and a second electrode on the substrate. The method comprises generating a predefined range of micrometer gap between the first electrode and the second electrode. Thereafter, the method comprises casting the predefined range of micrometer gap using the light-sensitive metal-oxide material.

In an embodiment, the present disclosure relates to a device for fabricating a photodetector. The device includes a processor and a memory communicatively coupled to the processor. The memory stores processor-executable instructions, which, on execution, cause the processor to fabricate the photodetector. The device receives a substrate for fabricating a photodetector, wherein the substrate is of a predefined dimension based on user requirement. The device develops a first electrode and a second electrode on the substrate. The device generates a predefined range of micrometer gap between the first electrode and the second electrode.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF DRAWINGS

The accompanying drawings, which are incorporated in and constitute a part of this disclosure, illustrate exemplary embodiments and, together with the description, serve to explain the disclosed principles. In the figures, the left-most digit(s) of a reference number identifies the figure in which the reference number first appears. The same numbers are used throughout the figures to reference like features and components. Some embodiments of device or system and/or methods in accordance with embodiments of the present subject matter are now described, by way of example only, and with reference to the accompanying figures, in which:

FIG. 1 shows an exemplary environment of a device for fabricating a photodetector, in accordance with some embodiments of the present disclosure;

FIG. 2 shows a detailed block diagram of a device for fabricating a photodetector, in accordance with some embodiments of the present disclosure;

FIG. 3 shows a photodetector for an optical sensing instrument, in accordance with some embodiments of the present disclosure;

FIGS. 4a-4d illustrates graphs showing results of examination of Mn3O4 crystal using X-ray diffraction, Raman spectroscopy and UV-Visible spectroscopy measurements, in accordance with some embodiment of present disclosure;

FIGS. 5a-5e illustrates graphs showing results of device against different wavelength of light, in accordance with some embodiment of present disclosure;

FIG. 6 illustrates a flowchart showing exemplary method for fabricating a photodetector, in accordance with some embodiments of present disclosure; and

FIG. 7 illustrates a block diagram of an exemplary computer system for implementing embodiments consistent with the present disclosure.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and executed by a computer or processor, whether such computer or processor is explicitly shown.

### DETAILED DESCRIPTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood, however that it is not intended to limit the disclosure to the forms disclosed, but on the contrary, the disclosure is to cover all modifications, equivalents, and alternative falling within the spirit and the scope of the disclosure.

The terms “comprises”, “comprising”, or any other variations thereof, are intended to cover a non-exclusive inclusion, such that a setup, device, or method that comprises a list of components or steps does not include only those components or steps but may include other components or steps not expressly listed or inherent to such setup or device or method. In other words, one or more elements in a system or apparatus proceeded by “comprises . . . a” does not, without more constraints, preclude the existence of other elements or additional elements in the system or method.

The terms “includes”, “including”, or any other variations thereof, are intended to cover a non-exclusive inclusion, such that a setup, device, or method that includes a list of components or steps does not include only those components or steps but may include other components or steps not expressly listed or inherent to such setup or device or method. In other words, one or more elements in a system or apparatus proceeded by “includes . . . a” does not, without more constraints, preclude the existence of other elements or additional elements in the system or method.

In the following detailed description of the embodiments of the disclosure, reference is made to the accompanying drawings that form a part hereof, and in which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

Present disclosure relates to a method and a device for fabricating a photodetector. The device of the present disclosure receives a substrate for fabricating the photodetector. The substrate is of a predefined dimension based on user requirement. The device of the present disclosure develops a first electrode and a second electrode on the substrate. The device of the present disclosure generates a predefined range of micrometer gap between the first electrode and the second electrode. Thereafter, the device of the present disclosure casts the predefined range of micrometer gap using the light-sensitive metal-oxide material. Thus, the present disclosure is able to generate a photodetector at low-cost and reduced fabrication time.

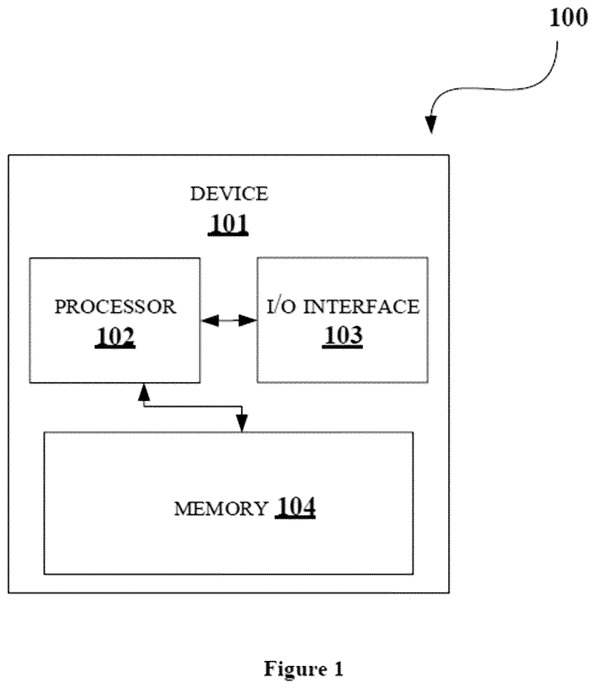

FIG. 1 shows an exemplary environment 100 for fabricating a photodetector. The environment 100 may include a device 101. The device 101 may include a processor 102, a I/O interface 103, and a memory 104. In some embodiments, the memory 104 may be communicatively coupled to the processor 102. The memory 104 stores instructions, executable by the processor 102, which, on execution, may cause the device 101 to fabricate the photodetector, as disclosed in the present disclosure.

In an embodiment, the device 101 may communicate with a user via a communication network (not shown in FIG. 1). In an embodiment, the communication network may include, without limitation, a direct interconnection, Local Area Network (LAN), Wide Area Network (WAN), Controller Area Network (CAN), wireless network (e.g., using a Wireless Application Protocol), the Internet, and the like.

The device 101 receives a substrate for fabricating the photodetector. The substrate is of a predefined dimension based on user requirement. In an embodiment, the substrate is made of silicon oxide (SiO₂) grown Si wafer. Upon receiving the substrate, the device 101 develops a first electrode and a second electrode on the substrate. In an embodiment, the first electrode and the second electrode are developed by printing one or more patterns on the substrate using nanoparticle material. In an embodiment, the nanoparticle material is a silver material. Further, the device 101 heats the first electrode ad the second electrode slowly to a predetermined temperature for a predefined time period. Further, the device 101 generates a predefined range of micrometer gap between the first electrode and the second electrode. The predefined range is between 5 micrometer and 35 micrometer. Upon generating, the device casts the predefined range of micrometer gap using a light-sensitive metal-oxide material. The light-sensitive metal-oxide material is synthesized by chemical co-precipitation method. In an embodiment, the light-sensitive metal-oxide material is manganese oxide (Mn3O4). In an embodiment, while casting the predefined range, the device performs aqueous dispersion of the light-sensitive metal-oxide material over the predefined range of micrometer gap between the first electrode and the second electrode for fabricating the photodetector. In an embodiment, the photodetector responses over a broad wavelength spectrum ranging from 245 nanometer to 1000 nanometer.

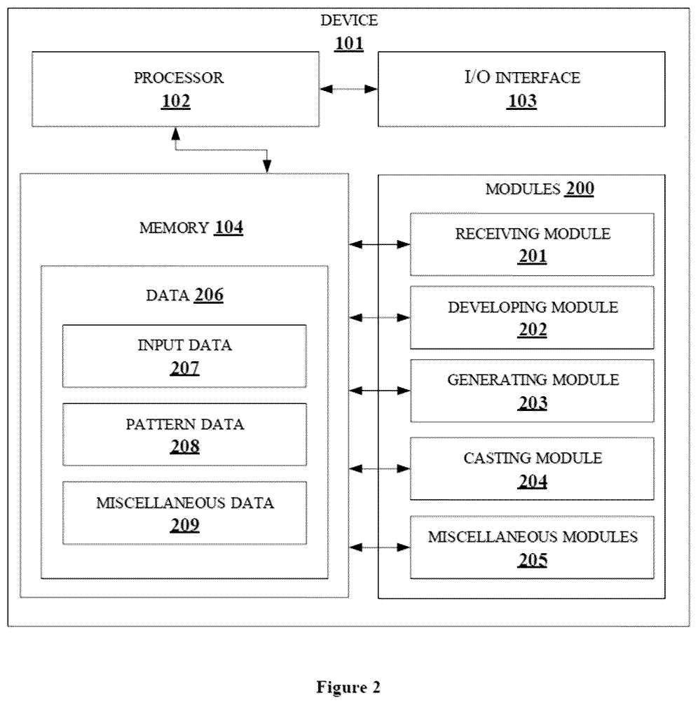

FIG. 2 shows a detailed block diagram of a device for fabricating a photodetector, in accordance with some embodiments of the present disclosure.

Data 206 and one or more modules 200 in the memory 104 of the device 101 is described herein in detail.

In one implementation, the one or more modules 200 (also referred as means) may include, but are not limited to, a receiving module 201, a developing module 202, a generating module 203, a casting module204, and one or more miscellaneous modules 205, associated with the device 101.

In an embodiment, the data 206 in the memory 104 may include input data 207, pattern data 2 and miscellaneous data 209 associated with the device 101.

In an embodiment, the data 206 in the memory 104 may be processed by the one or more modules 200 of the device 101. In an embodiment, the one or more modules 200 may be implemented as dedicated units and when implemented in such a manner, said modules may be configured with the functionality defined in the present disclosure to result in a novel hardware. As used herein, the term module may refer to an Application Specific Integrated Circuit (ASIC), an electronic circuit, a Field-Programmable Gate Arrays (FPGA), Programmable System-on-Chip (PSoC), a combinational logic circuit, and/or other suitable components that provide the described functionality.

One or more modules 200 of the present disclosure function to fabricate the photodetector. The one or more modules 200 may also include miscellaneous modules 205 to perform various miscellaneous functionalities of the device 101. It will be appreciated that such modules may be represented as a single module or a combination of different modules. The one or more modules 200 along with the data 206, may be implemented in any device, for fabricating the photodetector.

In an embodiment, the data 206 in the memory 104 is processed by the one or more means 200 of the device 101. The one or more means 200 may be implemented as dedicated hardware units. As used herein, the term module or means refers to an Application Specific Integrated Circuit (ASIC), an electronic circuit, a Field Programmable Gate Arrays (FPGA), Programmable System on Chip (PSoC), a combinational logic circuit, and/or other suitable components that provide the described functionality. In some implementations, the one or more means 200 are communicatively coupled to each other for performing one or more functions of the device 101. The one or more means 200 when configured with the functionality defined in the present disclosure will result in a novel hardware. In another embodiment, the data 206 in the memory 104 is processed by the one or more means (also, referred as modules) 200 of the memory 104 of the device 101.

The input data 207 may include information regarding dimensions of substrate, predetermined temperature and predefined time period obtained from user. The dimension of the substrate, predetermined temperature, and predefined time period varies based on application of the photodetector.

The pattern data 208 may include information regarding one or more patterns printed for developing first and second electrodes. The one or more patterns may be obtained from a user based on application of the photodetector.

The miscellaneous data 209 may store data, including temporary data and temporary files, generated by modules for performing the various functions of the device 101.

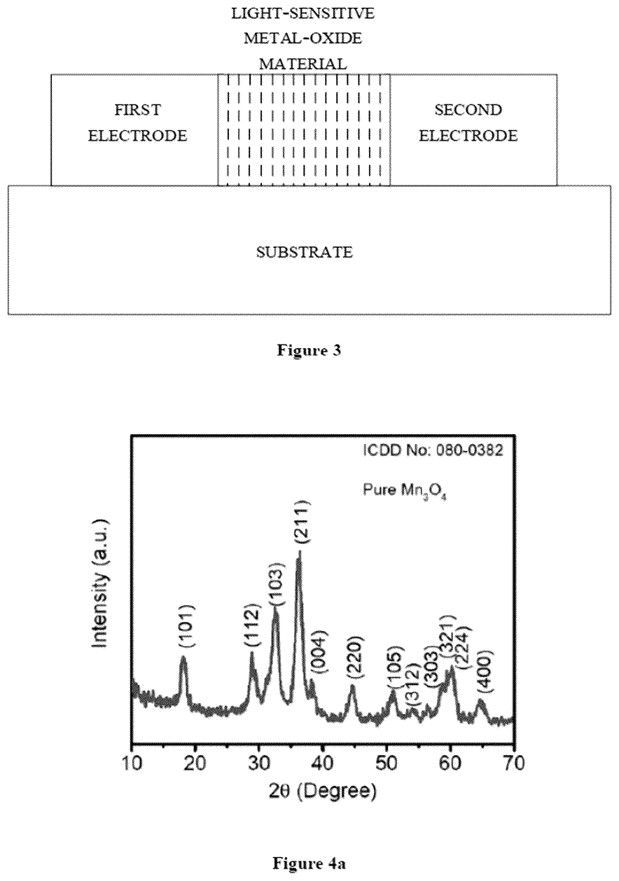

The receiving module 201 receives a substrate for fabricating a photodetector. The substrate is of a predefined dimension based on user requirement. In an embodiment, the substrate is an undoped SiO₂-grown Si wafer. A person skilled in the art may understand that the substrate may be any material depending on the application and is not limited to Si or silicon oxide. The Si wafer is cut into the predefined dimension with a diamond cutter. The substrate is cleaned with but not limited to acetone and piranha solution. Further the substrate is rinsed two-three times with Demineralized (DM) water and an Isopropyl Alcohol (IPA) solution before being blow-dried with nitrogen gas. The developing module 202 develops a first electrode and a second electrode on the substrate (as shown in FIG. 3). The developing module 202 prints one or more patterns on the substrate using nanoparticle material. In an embodiment, to develop the first electrode and the second electrode above the cleaned substrate (also referred as oxide wafer), Silver (Ag) nanoparticle material electrodes are printed through the device 101

In an embodiment, the device 101 is loaded with silver nanoparticle material ink for developing the first electrode and the second electrode. While developing the first and the second electrode, the substrate surface is gently touched with the micro tip of the device 101. The one or more pattern is created by gently dragging the micro tip along the surface in accordance with the design requirement. A person skilled in art may understand that the design of the one or more patterns depends on the type of application, user requirement and is not limited to one design or pattern. Upon printing one or more pattern, the developing module 202 heats the first electrode and the second electrode slowly to a predetermined temperature for a predefined time period. In an embodiment, the device 101 may be associated with a heater for heating the first and second electrode. For example, the first and the second electrode are slowly heated to 90° C. to solidify the ink. Further, the substrate is taken out and heated to 90° C. for 10 minutes.

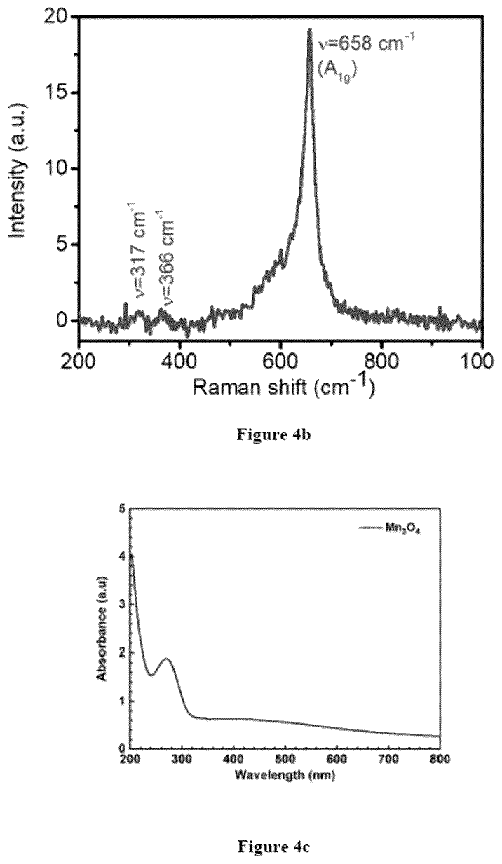

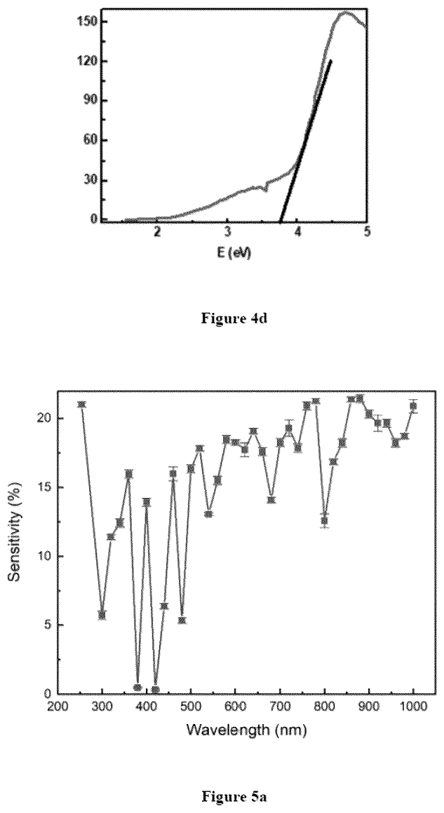

In an embodiment, the generating module 203 generates a predefined range of micrometer gap between the first electrode and the second electrode. The predefined range of micrometer gap is 30 μm. The casting module 204 casts the predefined range of micrometer gap using a light-sensitive metal-oxide material. The light-sensitive metal-oxide material is Mn3O4. In an embodiment, prior to casting the light-sensitive metal-oxide material, the light-sensitive metal-oxide material is synthesized by chemical co-precipitation method. For example, 0.31 of Manganese Acetate (Mn(CH₃CO₂)₂) is added to 25 mL of Dimethylformamide (DMF)-water solution (DMF≈20 mL and water≈5 mL) under constant stirring. Further, 2 mM Sodium hydroxide (NaOH) solution is prepared separately and added dropwise to the first solution until the solution pH reaches 8.5. Once the solution becomes brown color, the solution is constantly stirred for four hours. The concentrated solution is centrifuged to obtain the Mn₃O₄ nanoparticle powder. Thereafter, the final product is filtered and washed with Deionized (DI) water and then ethanol three-four times. The Mn₃O₄ material is then dried in the oven at 80° C. overnight. In an embodiment, a person skilled in art may understand that the Mn₃O₄ may be prepared using different method and different material such as manganese nitrate, manganese chloride, manganese hydroxide, manganese oxalate, potassium hydroxide and is not limited to the co-precipitation method and the manganese acetate as discussed above. In an embodiment, the crystal structure of the prepared Mn3O4 nanoparticles is examined using X-ray diffraction, Raman spectroscopy, and UV-Visible spectroscopy measurements. The results are shown in FIGS. 4a-4d.

In an embodiment, the casting module 204 performs aqueous dispersion of the prepared light-sensitive metal-oxide material over the predefined range of micrometer gap between the first electrode and the second electrode. For example, two μL of Mn3O4 aqueous dispersion (1 mg of Mn₃O₄ in 1 mL of DI water) is drop cast over 30 μm gap between the first electrode and the second electrode (as shown in FIG. 3). Upon casting, the light-sensitive metal-oxide material is heated at 90° C. for ten minutes to fabricate the photodetector.

FIGS. 4a-4d illustrates graphs showing results of examination of Mn₃O₄ crystal using X-ray diffraction, Raman spectroscopy, and UV-Visible spectroscopy measurements, in accordance with some embodiment of present disclosure.

FIG. 4a shows the X-Ray diffraction (XRD) patterns of synthesized Mn3O4 nanoparticles indicating the formation of single phase and the peaks were indexed with ICDD card no. 080-0382. In an embodiment, the ICDD is the International Centre for Diffraction Data and the ICDD card No. represents a standard diffraction pattern for a particular crystal structure. FIG. 4a results indicate pure tetragonal phase formation. In an embodiment, other impurity peaks associated with the synthesized material is not evident in FIG. 4a, indicating pure tetragonal phase formation. In an embodiment, the XRD pattern compared to standard ICDD No. confirms the formation of the particular crystal structure of the synthesized material without any impurity.

In an embodiment, as shown in FIG. 4b, three Raman peaks at 317, 366, and 658 cm-1 are observed and is assigned to the presence of the pure Mn₃O₄ phase (MnO·Mn₂O₃ in spinel notation). The very sharp peak at 658 cm-1 is assigned to the Alg mode in spinel structures, which corresponds to the Mn—O breathing vibration of divalent manganese ions in tetrahedral coordination. In an embodiment, the Alg mode is a Raman active vibration mode in tetragonal spinel Mn₃O₄. The Alg vibration mode is due to the respiratory vibration of Mn₂p ions in a tetragonal Mn₃O₄ phase. The other two smaller peaks located at 317 and 366 cm-1 are assigned to the combined vibrations of tetrahedral and octahedral oxygen atoms. The Raman spectrum also confirms the formation of phase pure Mn₃O₄ prepared through the synthesis method.

In an embodiment, the optical properties of Mn₃O₄ nanomaterial are investigated using a UV-Visible (UV-vis) spectrophotometer. The UV-vis absorbance spectra of the prepared Mn₃O₄ nanomaterial are shown in FIG. 4c. In an embodiment, Tauc's formula, gives the correlation between photon energy (h) and absorption coefficient (a), and is used to calculate the optical bandgap energy of the materials. Tauc's formula is expressed as given below:

$$α hv = A ( hv - Eg ) n \qquad ( 1 )$$

In an embodiment, FIG. 4d shows the optical bandgap energy of the material. The optical bandgap of the nanomaterial, derived from the tauc plot, is 3.7 eV. The stable room-temperature phase is tetragonal hausmannite, with Mn₃₊ and Mn₂₊ ions occupying the spinel structure's octahedral and tetrahedral positions. The octahedral symmetry is tetragonally distorted due to the Jahn-Teller effect on Mn3+ ions. In an embodiment, the UV visible spectrum gives the information about the optical properties and the band gap energy can be calculated from the UV visible spectrum through tauc formula. The band gap energy is a very important parameter for electronic and optoelectronic devices. The band gap energy has significant effect on the response of the photodiode/device 101.

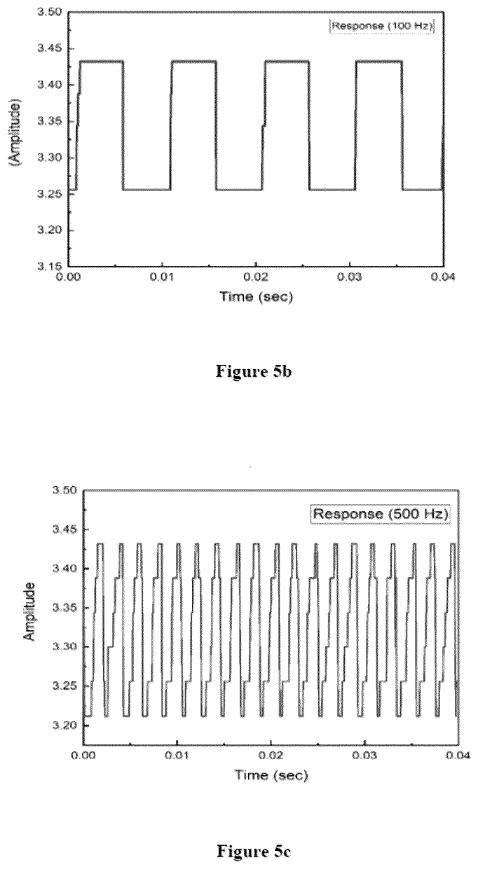

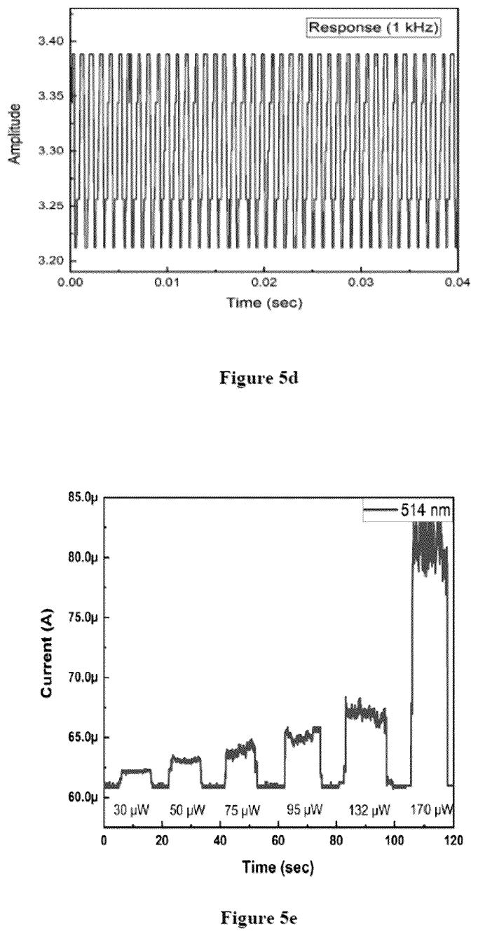

In an embodiment, the fabricated photodetector is analysed to evaluate the photodetectors electrical features. In an embodiment, a keithly 4200A-SCS parametric analyser is utilised for the analysis. The I-V characteristics of various wavelengths ranging from 240 to 1000 nm are measured by sweeping a voltage from −5 to 5 V. In an embodiment, the analysis is performed with a 100 μW light source. In an embodiment, the sensor baseline measurement is performed in the dark condition. Further, a series of experiments are carried out using different light wavelengths to evaluate the photodiode's response to varying light wavelengths toward a constant light power source, and the corresponding I-V characteristics are obtained. The sensor/photodetector shows a good response over a wavelength of 250 nm to 1000 nm and especially in between 500 to 1000 nm. The sensor sensitivity plotted against a different light wavelength is displayed in FIG. 5a. In an embodiment, the light sensing material provides a broad band response. The sensor/photodetector sensitivity is represented as below:

$$S = \frac{\vert {R}_{g} - {R}_{o} \vert}{{R}_{o}} \times 100 \% \qquad ( 2 )$$

where, R₀ denotes the device's Average Electrical Resistance (AER) in the dark and R_{g} denotes the AER of photodiode/photodetector for various light wavelengths.

In an embodiment, the sensor has a very high sensitivity of 21.45% for light at 880 nm and a very low sensitivity of 0.32% for light at 420 nm. For validating the frequency response of the sensor, it is connected to a voltage divider circuit and a Light Emitting-Diode (LED) is used as light source supplied with a square-wave signal from a waveform generator, and the results were monitored on a Digital Storage Oscilloscope (DSO). The device is tested at 100, 500, and 1000 Hz, and the results are depicted in FIGS. 5b-5d. The photodiode shows a good frequency response, with a recovery time of 15 μs. FIG. 5b-5d shows that the sensor shows very good response even at high frequencies of 1 kHz. In an embodiment, FIG. 5e demonstrates the photo response current-transient of the light power range from 30 μW to 170 μW, with a bias voltage of 2V. It exhibits a distinguishable response for each light power level. In an embodiment, FIG. 5e clearly indicates that the output current of the sensor increases with light intensity and a very good response is obtained at a very low power of 30 μW that is excellent for detecting very low power light.

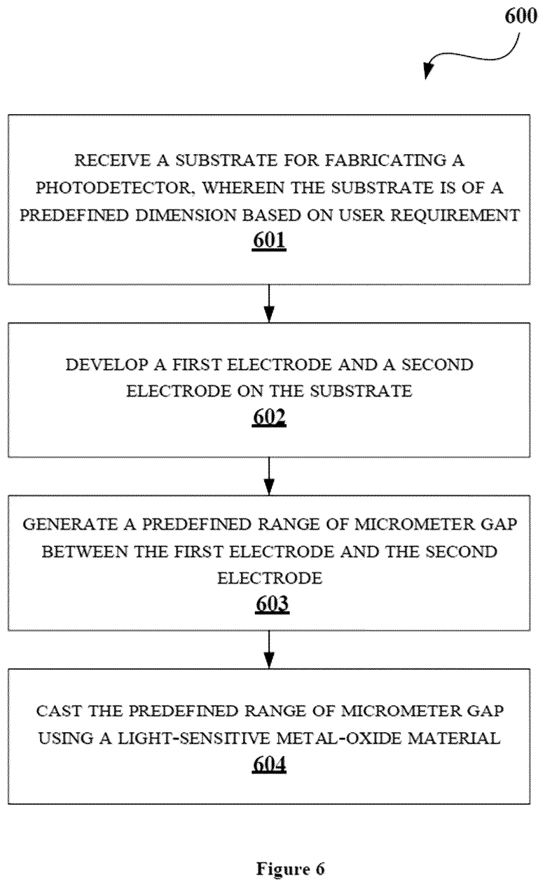

FIG. 6 illustrates a flow diagram showing an exemplary method for fabricating a photodetector, in accordance with some embodiments of present disclosure.

As illustrated in FIG. 6, the method 600 may include one or more blocks for executing processes in the device 101. The method 600 may be described in the general context of computer executable instructions. Generally, computer executable instructions can include routines, programs, objects, components, data structures, procedures, modules, and functions, which perform functions or implement abstract data types.

The order in which the method 600 are described may not intended to be construed as a limitation, and any number of the described method blocks can be combined in any order to implement the method. Additionally, individual blocks may be deleted from the methods without departing from the scope of the subject matter described herein. Furthermore, the method can be implemented in any suitable hardware, software, firmware, or combination thereof.

At step 601, receiving, by the receiving module 201, a substrate for fabricating the photodetector. The substrate is of a predefined dimension based on user requirement.

At step 602, developing, by the developing module 202, a first electrode and a second electrode on the substrate. Firstly, one or more patterns are printed on the substrate using nanoparticle material. Then, the first electrode and the second electrode are heated slowly to a predetermined temperature for a predefined time period.

At step 603, generating, by the generating module 203, a predefined range of micrometer gap between the first electrode and the second electrode. The predefined range is between 5 micrometer and 35 micrometer.

At step 604, casting, by the casting module 204, the predefined range of micrometer gap using light-sensitive metal-oxide material. Firstly, aqueous dispersion of the light-sensitive metal-oxide material is performed over the predefined range of micrometer gap between the first electrode and the second electrode to fabricate the photodetector.

### Computing System

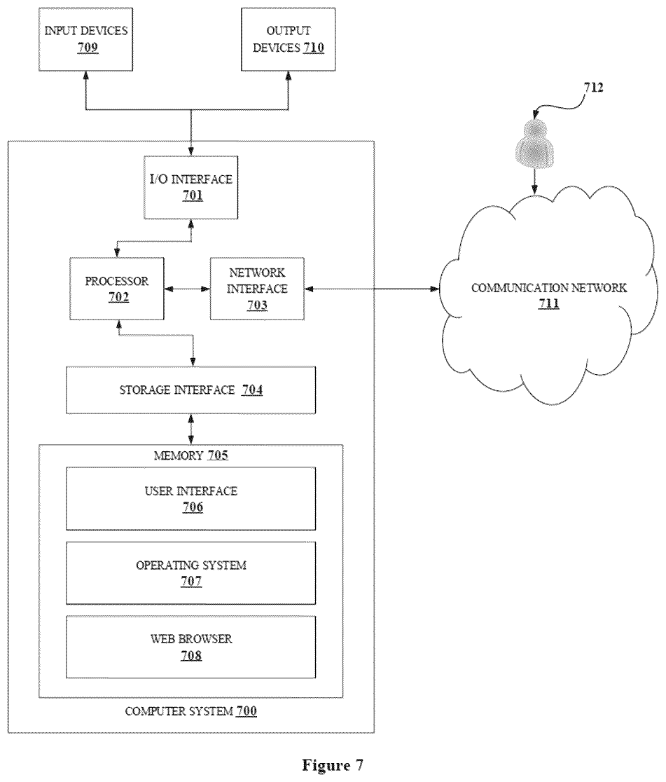

FIG. 7 illustrates a block diagram of an exemplary computer system 700 for implementing embodiments consistent with the present disclosure. In an embodiment, the computer system 700 is used to implement the device 101. The computer system 700 may include a central processing unit (“CPU” or “processor”) 702. The processor 702 may include at least one data processor for executing processes in Virtual Storage Area Network. The processor 702 may include specialized processing units such as, integrated system (bus) controllers, memory management control units, floating point units, graphics processing units, digital signal processing units, etc.

The processor 702 may be disposed in communication with one or more input/output (I/O) devices 709 and 710 via I/O interface 701. The I/O interface 701 may employ communication protocols/methods such as, without limitation, audio, analog, digital, monaural, RCA, stereo, IEEE-1394, serial bus, universal serial bus (USB), infrared, PS/2, BNC, coaxial, component, composite, digital visual interface (DVI), high-definition multimedia interface (HDMI), RF antennas, S-Video, VGA, IEEE 802.n/b/g/n/x, Bluetooth, cellular (e.g., code-division multiple access (CDMA), high-speed packet access (HSPA+), global system for mobile communications (GSM), long-term evolution (LTE), WiMax, or the like), etc.

Using the I/O interface 701, the computer system 700 may communicate with one or more I/O devices 709 and 710. For example, the input devices 709 may be an antenna, keyboard, mouse, joystick, (infrared) remote control, camera, card reader, fax machine, dongle, biometric reader, microphone, touch screen, touchpad, trackball, stylus, scanner, storage device, transceiver, video device/source, etc. The output devices 710 may be a printer, fax machine, video display (e.g., cathode ray tube (CRT), liquid crystal display (LCD), light-emitting diode (LED), plasma, Plasma display panel (PDP), Organic light-emitting diode display (OLED) or the like), audio speaker, etc.

In some embodiments, the computer system 700 may consist of the device 101 which communicates with a user 712 to fabricate photodetector. The processor 702 may be disposed in communication with the communication network 711 via a network interface 703. The network interface 703 may communicate with the communication network 711. The network interface 703 may employ connection protocols including, without limitation, direct connect, Ethernet (e.g., twisted pair 10/100/1000 Base T), transmission control protocol/internet protocol (TCP/IP), token ring, IEEE 802.11a/b/g/n/x, etc. The communication network 711 may include, without limitation, a direct interconnection, local area network (LAN), wide area network (WAN), wireless network (e.g., using Wireless Application Protocol), the Internet, etc. Using the network interface 703 and the communication network 711, the computer system 700 may communicate with a user for fabricating photodetector. The network interface 703 may employ connection protocols include, but not limited to, direct connect, Ethernet (e.g., twisted pair 10/100/1000 Base T), transmission control protocol/internet protocol (TCP/IP), token ring, IEEE 802.11a/b/g/n/x, etc.

The communication network 711 includes, but is not limited to, a direct interconnection, an e-commerce network, a peer to peer (P2P) network, local area network (LAN), wide area network (WAN), wireless network (e.g., using Wireless Application Protocol), the Internet, Wi-Fi, and such. The first network and the second network may either be a dedicated network or a shared network, which represents an association of the different types of networks that use a variety of protocols, for example, Hypertext Transfer Protocol (HTTP), Transmission Control Protocol/Internet Protocol (TCP/IP), Wireless Application Protocol (WAP), etc., to communicate with each other. Further, the first network and the second network may include a variety of network devices, including routers, bridges, servers, computing devices, storage devices, etc.

In some embodiments, the processor 702 may be disposed in communication with a memory 705 (e.g., RAM, ROM, etc. not shown in FIG. 7) via a storage interface 704. The storage interface 704 may connect to memory 705 including, without limitation, memory drives, removable disc drives, etc., employing connection protocols such as, serial advanced technology attachment (SATA), Integrated Drive Electronics (IDE), IEEE-1394, Universal Serial Bus (USB), fibre channel, Small Computer Systems Interface (SCSI), etc. The memory drives may further include a drum, magnetic disc drive, magneto-optical drive, optical drive, Redundant Array of Independent Discs (RAID), solid-state memory devices, solid-state drives, etc.

The memory 705 may store a collection of program or database components, including, without limitation, user interface 706, an operating system 707 etc. In some embodiments, computer system 700 may store user/application data 706, such as, the data, variables, records, etc., as described in this disclosure. Such databases may be implemented as fault-tolerant, relational, scalable, secure databases such as Oracle® or Sybase®.

The operating system 707 may facilitate resource management and operation of the computer system 700. Examples of operating systems include, without limitation, APPLE MACINTOSH® OS X, UNIX®, UNIX-like system distributions (E.G., BERKELEY SOFTWARE DISTRIBUTION™ (BSD), FREEBSD™, NETBSD™, OPENBSD™, etc.), LINUX DISTRIBUTIONS™ (E.G., RED HAT™, UBUNTU™, KUBUNTU™, etc.), IBM™ OS/2, MICROSOFT™ WINDOWS™ (XP™, VISTA™/7/8, 10 etc.), APPLE® IOS™, GOOGLE® ANDROID™, BLACKBERRY® OS, or the like.

Furthermore, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., be non-transitory. Examples include Random Access Memory (RAM), Read-Only Memory (ROM), volatile memory, non-volatile memory, hard drives, CD ROMs, DVDs, flash drives, disks, and any other known physical storage media.

### Advantages

An embodiment of the present disclosure provides a device with micro tip printing technology for fabricating photodetectors at low-cost and reduce fabrication time.

An embodiment of the present disclosure provides the device that operates at low temperature, low power consumption and is environmentally friendly.

An embodiment of the present disclosure utilises manganese oxide in the photodetector, which is beneficial in various fields, such as electronic devices, electrochemistry, catalysis, and medicine. The different oxidation states of manganese help to develop various manganese oxide materials such as manganese dioxide, di manganese trioxide, and tri manganese tetra oxide. Among different manganese oxide phases, the Hausmannite Mn₃O₄ phase of manganese is the most stable oxide at higher temperatures. It also has advantages for use in ion exchange, sensing, catalysts, batteries, and supercapacitors due to its various morphologies and oxidation states. Use of Mn₃O₄ is more suitable because of its accessibility, affordability, environmental friendliness, low cost, widespread availability of manganese, tuneable physicochemical properties, a wide range of optical absorption properties and abundant natural resources.

An embodiment of the present disclosure provides the photodetector that has a good sensitivity of more than 20% in the visible light spectra at 100 μW and a rapid recovery and response time.

An embodiment of the present disclosure provides the photodetector showing a response over a broad wavelength spectrum ranging from 245 nm to 1000 nm with high sensitivity and fast response time. Further, the photodetector is designed to vary the resistance when illuminated by the light on the metal-oxide nanoparticle.

The described operations may be implemented as a method, system or article of manufacture using standard programming and/or engineering techniques to produce software, firmware, hardware, or any combination thereof. The described operations may be implemented as code maintained in a “non-transitory computer readable medium”, where a processor may read and execute the code from the computer readable medium. The processor is at least one of a microprocessor and a processor capable of processing and executing the queries. A non-transitory computer readable medium may include media such as magnetic storage medium (e.g., hard disk drives, floppy disks, tape, etc.), optical storage (CD-ROMs, DVDs, optical disks, etc.), volatile and non-volatile memory devices (e.g., EEPROMs, ROMs, PROMs, RAMS, DRAMs, SRAMs, Flash Memory, firmware, programmable logic, etc.), etc. Further, non-transitory computer-readable media may include all computer-readable media except for a transitory. The code implementing the described operations may further be implemented in hardware logic (e.g., an integrated circuit chip, Programmable Gate Array (PGA), Application Specific Integrated Circuit (ASIC), etc.).

An “article of manufacture” includes non-transitory computer readable medium, and/or hardware logic, in which code may be implemented. A device in which the code implementing the described embodiments of operations is encoded may include a computer readable medium or hardware logic. Of course, those skilled in the art will recognize that many modifications may be made to this configuration without departing from the scope of the invention, and that the article of manufacture may include suitable information bearing medium known in the art.

The terms “an embodiment”, “embodiment”, “embodiments”, “the embodiment”, “the embodiments”, “one or more embodiments”, “some embodiments”, and “one embodiment” mean “one or more (but not all) embodiments of the invention(s)” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

A description of an embodiment with several components in communication with each other does not imply that all such components are required. On the contrary a variety of optional components are described to illustrate the wide variety of possible embodiments of the invention.

When a single device or article is described herein, it will be readily apparent that more than one device/article (whether or not they cooperate) may be used in place of a single device/article.

Similarly, where more than one device or article is described herein (whether or not they cooperate), it will be readily apparent that a single device/article may be used in place of the more than one device or article or a different number of devices/articles may be used instead of the shown number of devices or programs. The functionality and/or the features of a device may be alternatively embodied by one or more other devices which are not explicitly described as having such functionality/features. Thus, other embodiments of the invention need not include the device itself.

The illustrated operations of FIG. 6 show certain events occurring in a certain order. In alternative embodiments, certain operations may be performed in a different order, modified, or removed. Moreover, steps may be added to the above-described logic and still conform to the described embodiments. Further, operations described herein may occur sequentially or certain operations may be processed in parallel. Yet further, operations may be performed by a single processing unit or by distributed processing units.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on.

Accordingly, the disclosure of the embodiments of the invention is intended to be illustrative, but not limiting, of the scope of the invention, which is set forth in the following claims.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

Referral numerals:

| Reference | |
|---|---|
| Number | Description |
| 100 | Environment |
| 101 | Device |
| 102 | Processor |
| 103 | I/O interface |
| 104 | Memory |
| 200 | Modules |
| 201 | Receiving module |
| 202 | Developing module |
| 203 | Generating module |
| 204 | Casting module |
| 205 | Miscellaneous modules |
| 206 | Data |
| 207 | Input data |
| 208 | Pattern data |
| 209 | Miscellaneous data |
| 700 | Computer system |
| 701 | I/O interface |
| 702 | Processor |
| 703 | Network interface |
| 704 | Storage interface |
| 705 | Memory |
| 706 | User interface |
| 707 | Operating system |
| 708 | Web browser |
| 709 | Input devices |
| 710 | Output devices |
| 711 | Communication |
| | network |
| 712 | User |

What we claim is:

1. A method of fabricating a photodetector, the method comprising:
receiving, by a device, a substrate for fabricating the photodetector, wherein the substrate is of a predefined dimension based on user requirement;
developing, by the device, a first electrode and a second electrode on the substrate;
generating, by the device, a predefined range of micrometer gap between the first electrode and the second electrode; and
casting, by the device, the predefined range of micrometer gap using a light-sensitive metal-oxide material.

2. The method as claimed in claim 1, wherein developing the first electrode and the second electrode comprises:
printing, by the device, one or more patterns on the substrate using nanoparticle material; and
heating, by the device, the first electrode and the second electrode slowly to a predetermined temperature for a predefined time period.

3. The method as claimed in claim 1, wherein the casting comprises:
performing, by the device, aqueous dispersion of the light-sensitive metal-oxide material over the predefined range of micrometer gap between the first electrode and the second electrode.

4. The method as claimed in claim 1, further comprises:
synthesizing, by the device, the light-sensitive metal-oxide material by a chemical co-precipitation method.

5. The method as claimed in claim 4, wherein the light-sensitive metal-oxide material is a manganese oxide (Mn₃O₄).

6. The method as claimed in claim 1, wherein the predefined range is between 5 micrometer and 35 micrometer.

7. The method as claimed in claim 1, wherein the photodetector responses over a broad wavelength spectrum ranging from 245 nanometer to 1000 nanometer.

8. The method as claimed in claim 1, wherein the photodetector comprises a broad absorption range between Ultraviolet range and Infrared range.

9. A device for fabricating a photodetector, comprising:
a processor; and
a memory communicatively coupled to the processor, wherein the memory stores processor-executable instructions, which, on execution, cause the processor to:
receive a substrate for fabricating the photodetector, wherein the substrate is of a predefined dimension based on user requirement;
develop a first electrode and a second electrode on the substrate;
generate a predefined range of micrometer gap between the first electrode and the second electrode; and
cast the predefined range of micrometer gap using a light-sensitive metal-oxide material.

10. The device as claimed in claim 9, wherein the processor is configured to develop the first electrode and the second electrode by:
printing one or more patterns on the substrate using nanoparticle material; and
heating the first electrode and the second electrode slowly to a predetermined temperature for a predefined time period.

11. The device as claimed in claim 9, wherein the processor is configured to cast by performing aqueous dispersion of the light-sensitive metal-oxide material over the predefined range of micrometer gap between the first electrode and the second electrode.

12. The device as claimed in claim 9, wherein the light-sensitive metal-oxide material is a manganese oxide (Mn₃O₄), wherein the light-sensitive metal-oxide material is synthesized by a co-precipitation method.

13. The device as claimed in 12, wherein the manganese oxide (Mn₃O₄) is having crystalline structure and is spinel Mn₃O₄.

14. The device as claimed in claim 9, wherein the predefined range is between 5 micrometer and 35 micrometer.

15. The device as claimed in claim 9, wherein the photodetector responses over a broad wavelength spectrum ranging from 245 nanometer to 1000 nanometer.

16. The device as claimed in claim 9, wherein the photodetector comprises a broad absorption range between Ultraviolet range and Infrared range.

17. A photodetector for an optical sensing instrument, comprising:
a substrate of a predefined dimension based on user requirement and is made of silicon oxide;
a first electrode and a second electrode developed by printing one or more patterns on the substrate using nanoparticle material; and
a light-sensitive metal-oxide material cast over a predefined range of micrometer gap between the first electrode and the second electrode.

18. The photodetector as claimed in claim 17, wherein the nanoparticle material is a silver material.

19. The photodetector as claimed in claim 17, wherein the light-sensitive metal-oxide material is a manganese oxide (Mn₃O₄).

20. The photodetector of claim 17, wherein the predefined range is between 5 micrometer and 35 micrometer.
